(19) United States
(12) Patent Application Publication
(10) Pub. No.: US 2024/0297585 A1
(43) Pub. Date: Sep. 5, 2024

(54) ADAPTIVE ERROR AMPLIFIER CLAMP FOR A PEAK CURRENT MODE CONVERTER

(71) Applicant: TEXAS INSTRUMENTS INCORPORATED, Dallas, TX (US)

(72) Inventors: Fangli Ge, Shanghai (CN); Luyang He, Nanjing (CN); Ding Yan, Dallas, TX (US)

(21) Appl. No.: 18/177,276

(22) Filed: Mar. 2, 2023

(51) Int. Cl. H02M 3/158; H02M 1/32; H03K 3/037; H03K 5/24

(52) U.S. Cl. CPC H02M 3/1582; H02M 1/32; H03K 3/037; H03K 5/24

(57) ABSTRACT

A voltage converter includes an amplifier, a voltage-to-current (VtoI) converter circuit, a current mirror, a slope generation circuit, and a transistor. The amplifier has an amplifier output. The VtoI converter circuit has a VtoI input and a VtoI output. The VtoI input is coupled to the amplifier output. The current mirror has a current mirror input and a current mirror output. The current mirror input is coupled to the VtoI output. The slope generation circuit has an input coupled to the current mirror input. The transistor is coupled between the amplifier output and a reference terminal. The transistor has a control input coupled to the current mirror output.

### BACKGROUND

One type of voltage converter is a switching voltage converter which controls the frequency and duty cycle of one or more transistors to regulate an output voltage. Different types of control modes are used for switching voltage regulators. One type of control mode is peak current mode control in which current through a high side sense transistor is compared to a threshold to determine when to turn OFF a high side power transistor.

### SUMMARY

A voltage converter includes an amplifier, a voltage-to-current (VtoI) converter circuit, a current mirror, a slope generation circuit, and a transistor. The amplifier has an amplifier output. The VtoI converter circuit has a VtoI input and a VtoI output. The VtoI input is coupled to the amplifier output. The current mirror has a current mirror input and a current mirror output. The current mirror input is coupled to the VtoI output. The slope generation circuit has an input coupled to the current mirror input. The transistor is coupled between the amplifier output and a reference terminal. The transistor has a control input coupled to the current mirror output.

### BRIEF DESCRIPTION OF THE DRAWINGS

FIG. 1 is a schematic diagram of an example switching voltage converter in which a slope compensation current is generated outside of a control loop, in which the control loop prevents an output voltage from an error amplifier from exceeding an upper limit.

FIG. 2 is a graph illustrating the relationship between inductor current and the error amplifier's output voltage, in an example.

FIG. 3 is a schematic diagram of a buck converter in which a slope compensation current is generated inside of a control loop to clamp the output voltage from the error amplifier, in an example.

FIG. 4 is a schematic diagram of a boost converter in which a slope compensation current is generated inside of a control loop to clamp the output voltage from the error amplifier, in an example.

### DETAILED DESCRIPTION

The same reference numbers or other reference designators are used in the drawings to designate the same or similar (either by function and/or structure) features.

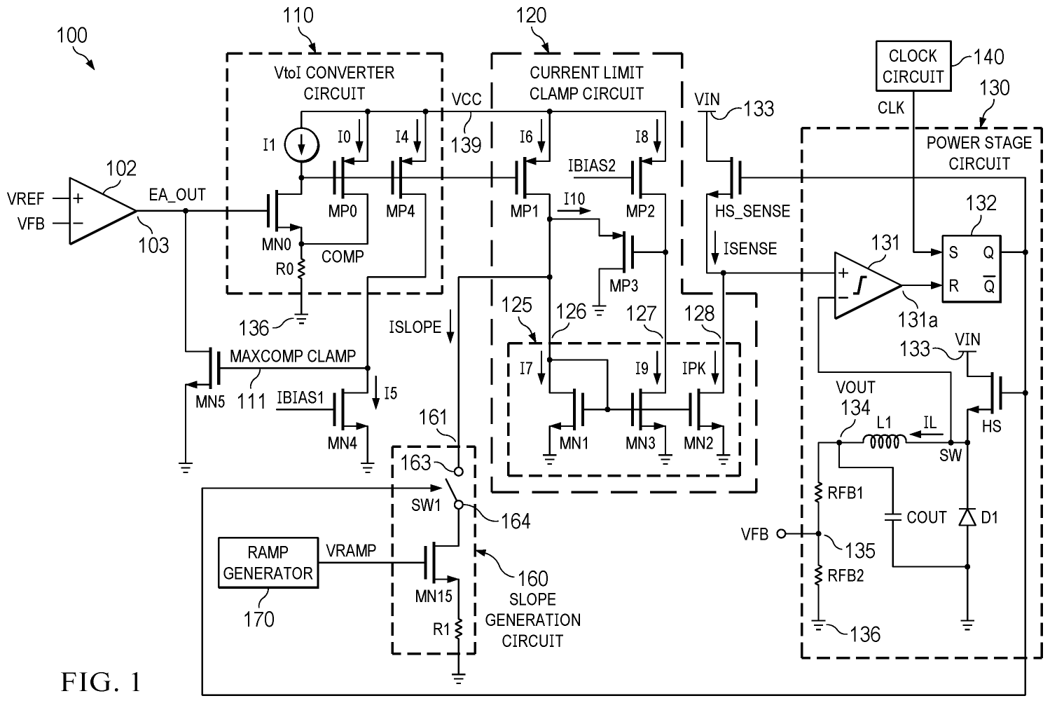

FIG. 1 is a schematic diagram of an example switching voltage converter 100 that includes an amplifier 102 (which may be referred to as an error amplifier), a voltage-to-current (VtoI) converter circuit 110, a current limit clamp circuit 120, a power stage circuit 130, a clock circuit 140, a slope generation circuit 160, a ramp generator 170, and transistors MN4, MN5, and HS_SENSE. The power stage circuit 130 has a voltage input (VIN) terminal 133 and a voltage output (VOUT) terminal 134. The voltage output terminal 134 is coupled to a voltage divider formed by the series coupling of resistors RFB1 and RFB2 between the VOUT terminal and a reference terminal 136 (e.g., ground). The output 135 of the voltage divider provides a feedback voltage VFB.

Amplifier 102 includes a positive (+, non-inverting) input, a negative (−, inverting) input, and an output 103. In this example, the output 135 of the voltage divider is coupled to the negative input of amplifier 102. The negative input of amplifier 102 thus receives the feedback voltage VFB from the power stage circuit 130. A reference voltage (VREF) is coupled to the amplifier's positive input. Amplifier 102 amplifies the difference between VREF and VFB to produce an output voltage EA_OUT on its output 103. The output voltage EA_OUT thus represents the magnitude of the difference between the reference voltage VREF and the converter's output voltage VOUT (via its proxy VFB). EA_OUT becomes larger as VOUT decreases, and EA_OUT becomes smaller as VOUT increases.

The VtoI converter 110 circuit 110 includes a current source I1 circuit (“I1” refers to both the current source and the magnitude of the current produced therefrom), a resistor R0, and transistors MP0, MP4, and MN0. In this example, transistors MP0 and MP4 are p-channel field effect transistors (PFETs) and transistor MN0 is an n-channel field effect transistor (NFET). The current source circuit I1 is coupled between an internal supply voltage rail VCC 139 and the drain of transistor MN0. Resistor R0 is coupled between the source of transistor MN0 and the reference terminal 136. The sources of transistors MP0 and MP4 are coupled together. The gates of transistors MP0 and MP4 also are coupled together and to the drain of transistor MN0. Transistors MP0 and MP4 are coupled together to form a current mirror (e.g., a 1:1 mirror ratio) in which the current I0 through transistor MP0 is mirrored as current I4 through transistor MP4.

The output voltage EA_OUT from amplifier 102 is the voltage on the gate of transistor MN0. Transistor MN0 is a source-follower in which the voltage (COMP) on the source of transistor MN0 follows the voltage on its gate (e.g., one threshold voltage below the gate voltage). The magnitude of the current through resistor R0 is the voltage across resistor R0 (COMP) divided by the resistance of resistor R0. This means that current I0 is proportional to COMP/R0. Accordingly, because the voltage COMP follows voltage EA_OUT, current I0 is a function of the voltage EA_OUT. In this way, the VtoI converter circuit 110 converts the amplifier's output voltage EA_OUT to a current I0. Current I0 is mirrored through transistor MP4 as the output current from the VtoI converter circuit 110.

Transistors MN4 and MN5 are NFETs in this example. The drain of transistor MN4 is coupled to the drain of transistor MP4. A bias voltage IBIAS1 is applied to the gate of transistor MN4 thereby causing the current I5 (a bias current) through transistor MN4 to be a fixed current level. The drain of transistor MN4 also is coupled to the gate of transistor MN5. The drain of transistor MN5 is coupled to the output 103 of amplifier 102, and the source of transistor MN5 is coupled to the reference terminal 136.

Transistors MN4 and MN5 form a control loop to prevent the magnitude of the amplifier's output voltage EA_OUT from exceeding an upper limit (referred as the “clamp voltage”). The voltage at the gate of transistor MN5 is a feedback control signal MAXCOMP CLAMP 111. With voltage EA_OUT below the clamp voltage, current I0 and thus I4 is smaller than current I5 and the control signal MAXCOMP CLAMP 111 on the gate of transistor MN5 is low enough to maintain transistor MN5 OFF. However, if EA_OUT attempts to increase above the clamp voltage, current I0 and thus I4 become larger than current I5 which causes current to flow into the gate of transistor MN5 raising the voltage magnitude of the control signal MAXCOMP CLAMP 111 thereby turning on transistor MN5 and pulling the amplifier's output voltage EA_OUT down towards the clamp voltage. The voltage EA_OUT is [(I1+I0)*R0]+Vgs_MN0, where Vgs_MN0 is the gate-to-source voltage transistor MN0. Because EA_OUT is clamped in response to transistor MN5 turning ON, and transistor MN5 turns ON when current I4 equals current I5, then EA_OUT clamps at a voltage that is equal to [(I1+I5)*R0]+Vgs_MN0. In effect, bias current I5 determines the clamp voltage for EA_OUT

The current limit clamp circuit 120 includes transistors MP1, MP2, MP3, MN1, MN2, and MN3. In this example, transistors MP1-MP3 are PFETs and transistors MN1-MN3 are NFETs but they can be implemented as other types of transistors in other examples. The gate of transistor MP1 is coupled to the gate of transistors MP0 and MP4. Accordingly, current I0 is also mirrored as current I6 through transistor MP1. The sources of transistors MP1 and MP2 are coupled together. The drain of transistor MP1 is coupled to the source of transistor MP3 and to the drain of transistor MN1. The drain of transistor MP1 also is coupled to the slope generation circuit 160. The drain of transistor MP2 is coupled to the gate of transistor MP3 and to the drain of transistor MN3. A bias voltage IBIAS2 is provided to the gate of transistor MP2. The drain of transistor MP3 is coupled to the reference terminal 136. The gates of transistors MN1, MN2, and MN3 are coupled together, and the sources of transistors MN1, MN2, and MN3 also are coupled together. Accordingly, transistors MN1-MN3 form a current mirror 125 (e.g., 1:1:1 mirror ratio) having a current mirror input 126 and current mirror outputs 127 and 128. Current I7 forced into the current mirror input 126 through transistor MN1 is mirrored through transistors MN3 and MN2. The mirrored current through transistor MN2 is designated as current IPK.

Transistor HS_SENSE is an NFET (but can be other than an NFET in other examples), whose source is coupled to the drain of transistor MN2. The drain of transistor HS_SENSE is coupled to the voltage input terminal 133.

The power stage circuit 130 in this example includes a comparator 131, a set(S)—reset (R) flip-flop, a high side (HS) transistor, a diode D1 (which alternatively may be replaced by a low side (LS) transistor), an inductor L1, a capacitor COUT, and the resistors RFB1 and RBF2 (described above). In this example, the power stage circuit 130 is an output power stage for a buck converter, and thus the switching voltage converter 100 in this example may be a buck converter. In other examples, the switching converter may be other types of switching converters such as a boost converter, a buck-boost converter, etc.

The HS transistor is a power transistor sized to accommodate the current IL through the inductor L1. The HS_SENSE transistor is substantially smaller (size being a function of the ratio of a transistor's channel width (W) to its channel length (L)) than the HS transistor. The gates of the HS_SENSE and HS transistors are coupled together and to the Q output of the SR flip-flop 132. The HS_SENSE transistor is turned ON and OFF based on the same control signal (e.g., the Q output of the SR flip-flop 132) that turns ON and OFF the HS transistor. Because the HS_SENSE transistor is smaller than the HS transistor, the magnitude of the current ISENSE through the HS_SENSE transistor is proportionately smaller than the magnitude of current IL through the HS transistor. Accordingly, current ISENSE is proportional to current IL.

Comparator 131 has a positive input, a negative input, and an output 131a. The positive input is coupled to the source of the HS_SENSE transistor and to the drain of transistor MN2. The negative input of comparator 131 is coupled to the source of the HS transistor and to the cathode of diode D1 at a switching (SW) terminal. The output 131a of comparator 131 is coupled to the R input of the SR flip-flop. The S input of the SR flip-flop is coupled to a clock output of the clock circuit 140. The clock circuit 140 generates an output clock CLK to the S input of the SR flip-flop 132. As described above, the Q output of the SR flip-flop is coupled to the gates of the HS_SENSE and HS transistors. Both the HS_SENSE and HS transistors turn ON responsive to the Q output of the SR flip-flop being logic high, which occurs upon the S input receiving a rising edge of CLK. Both the HS_SENSE and HS transistors turn OFF responsive to the Q output of the SR flip-flop being logic low, which occurs upon the R input receiving a logic high signal from comparator 131.

One terminal of inductor L1 is coupled to the cathode of diode D1 and to the source of the HS transistor. Capacitor COUT is coupled between the other terminal of inductor L1 and the reference terminal 136.

Current I6 through transistor MP1 is proportional to current I0, and current I0 is proportional to the amplifier's output voltage EA_OUT. Accordingly, current I6 is proportional to the amplifier's output voltage EA_OUT. Current I6 flows through transistor MN1 as current I7. Current I7 is mirrored as current IPK through transistor MN2. While the HS transistor is ON, transistor HS_SENSE is also on resulting in a current ISENSE equivalent to the current IPK flowing through the transistor HS_SENSE, current IL through the inductor L1 increases (e.g., linearly). Voltage at the positive input of the comparator 131 is VIN−IPK*RSENSE, where RSENSE can be resistance between source and drain of the transistor HS_SENSE or a separate sensing resistor coupled in series with the transistor HS_SENSE, and voltage at the negative input of the comparator 131 is VIN−IL*Rdson, where Rdson is resistance between source and drain of the transistor HS. While current IL is smaller than current IPK*RSENSE/Rdson, the comparator's output signal to the R input of the SR flip-flop is logic low. In this state, a logic high assertion of CLK at the S input of the SR flip-flop 132 causes the flip-flop's Q output to become logic high thereby maintaining ON the HS and HS_SENSE transistors. When current IL rises to the level of current IPK*RSENSE/Rdson, the positive input of comparator 131 exceeds the comparator's negative input, and the comparator's output 131a produces a logic high signal to the flip-flop's R input thereby causing the Q output of the flip-flop to become logic low. In response to the SR flip-flop 132 being reset, the HS and HS_SENSE transistors turn OFF.

The current limit clamp circuit 120 limits the maximum amplitude of IPK to prevent the inductor current IL from becoming too large. Otherwise, the current through the HS transistor may exceed a drain current rating for the transistor thereby possibly damaging the transistor. Transistor MP2 is biased by a fixed voltage IBIAS2 and thus produces a fixed current I8. The current I9 through transistor MN3 is a mirrored copy of current I7. As current I7 increases, current I9 also increases. As long as current I9 is smaller than current I8, transistor MP3 remains OFF. If current I9 exceeds current I8, the gate of transistor MP3 discharges thereby turning ON transistor MP3. With transistor MP3 ON, a portion of current I6 can now flow through transistor MP3 as current I10 to the reference terminal 136 rather than continuing to flow through transistor MN1. Thus, when transistor MP3 turns ON, current I7 remains approximately constant while current I10 increases. Limiting current I7 to an upper limit also limits current IPK to the upper limit. Transistors MP2, MP3, and MN3 form a control loop to impose an upper limit on current IPK. The upper limit for current IPK is a function of the fixed current I8 through transistor MP2.

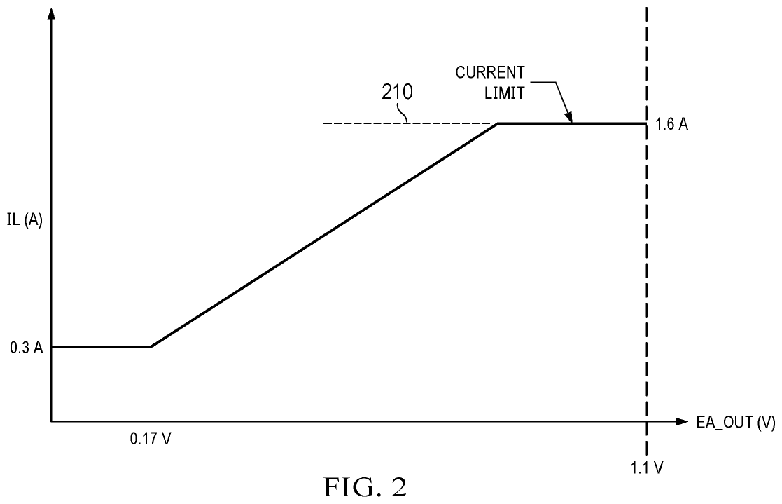

FIG. 2 is a graph illustrating an example relationship between inductor current IL and amplifier output voltage EA_OUT. When the HS transistor turns ON, the inductor current increases linearly as shown. The inductor current IL increases until the upper limit 210 is reached. The upper limit 210 is created by the control loop formed by transistors MP2, MP3, and MN3 as described above. In this example, the upper limit 210 that the inductor current IL is permitted to reach before the HS transistor is turned OFF is 1.6 A, but that limit is application-specific.

The slope compensation circuit 160 includes a switch SW1 (e.g., a transistor), a transistor MN15 (e.g., an NFET), and a resistor R1. The ramp generator 170 produces a ramp voltage VRAMP, which is provided to the gate of transistor MN15. In one example, the ramp generator includes a current source which is coupled to and charges a capacitor to create the ramp. A terminal 163 of switch SW1 is coupled to the drains of transistors MN1 and MP1 at the input 126 of current mirror 125 within the current limit clamp circuit 120. Transistor MN15 is coupled between the other terminal 164 of switch SW1 and resistor R1. In addition to controlling the ON/OFF state of the HS_SENSE and HS transistors, the Q output of the SR flip-flop is coupled to a control input of switch SW1 and thus also controls the ON/OFF state of switch SW1. At one logic state, (e.g., logic high), the Q output of the SR flip-flop turns ON all the HS and HS_SENSE transistors and causes switch SW1 to close (turn ON). In the other logic state (e.g., logic low) the Q output of the SR flip-flop turns OFF all the HS and HS_SENSE transistors and causes switch SW1 to open (turn OFF). With switch SW1 closed, as the ramp voltage VRAMP increases, the gate-to-source voltage (Vgs) of transistor MN15 increases thereby causing a slope compensation current ISLOPE to flow through resistor R1. The slope compensation current is a saw-tooth waveform in which the current linearly increases when switch SW1 is closed and VRAMP increases, and then falls back to 0 amperes when the HS transistor is OFF. Current I6 through transistor MP1 divides between the slope compensation current ISLOPE and current I7 through transistor MN1. Thus, the current I7 is the difference between current I6 and the slope compensation current ISLOPE. The current I7 is a slope-compensated function of the amplifier's output signal EA_OUT.

The architecture of the switching voltage converter 100 of FIG. 1 is such that the slope compensation current ISLOPE is generated outside the control loop formed by transistors MN4 and MN5 to prevent amplifier's output voltage EA_OUT from exceeding an upper threshold. That is, the slope compensation current ISLOPE is generated after the control loop formed by transistors MN4 and MN5. The control loop to limit the magnitude of EA_OUT includes the feedback control signal MAXCOMP CLAMP 111 taken, in this example, as the voltage on the drains of transistors MP4 and MN4. The feedback control signal MAXCOMP CLAMP 111 is generated without regard to the slope compensation current ISLOPE, which is generated partially within the current limit clamp circuit 120, at the input 126 of the current limit clamp circuit's current mirror 125. Accordingly, the current I7 into the current mirror input 126 of the current mirror 125 is a function of both the amplifier's output voltage EA_OUT and the slope compensation current ISLOPE. That the current I7 is a function of the slope compensation current ISLOPE means that the current IPK also is a function of the slope compensation current ISLOPE. The slope compensation current ISLOPE may be relatively large during conditions such as during start-up of the switching voltage converter 100 and/or when the input voltage VIN is below or close to the output voltage VOUT (e.g., large duty cycle conditions).

In some conditions with a large magnitude of the slope compensation current ISLOPE, the current IPK to which the inductor current IL is compared, as described above, may be small enough that the magnitude of current IL reaches current level IPK*RSENSE/Rdson at a current magnitude that is less than the maximum limit (e.g., 1.6 A in the example of FIG. 2). In such cases, the comparator 131 and SR flip-flop 132 will turn OFF the HS transistor before the inductor current IL reaches its target upper limit thereby making it difficult to accurately regulate the magnitude of the output voltage VOUT to the target level (e.g., 10 V, 15 V, etc.).

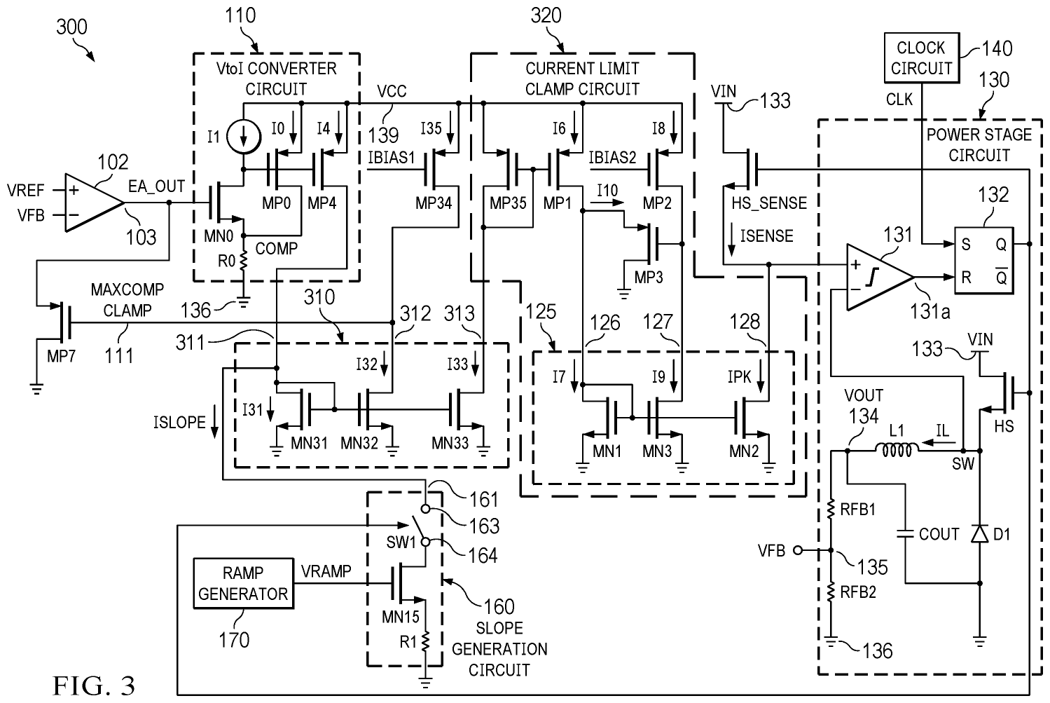

FIG. 3 is a schematic diagram of a switching voltage converter 300 that addresses the problem described above with regard to the switching voltage converter 100 of FIG. 1. Some circuits within the switching voltage converter 300 in FIG. 3 are identical to the corresponding circuits of the switching voltage converter 100 of FIG. 1, and such circuits are not described in detail with regard to FIG. 3—reference can be made above to the detailed descriptions of these circuits. For example, the switching voltage converter 300 includes the same VtoI converter circuit 110, power stage circuit 130, clock circuit 140, slope generation circuit 160, and ramp generator 170. The switching voltage converter 300 of FIG. 3 includes a current mirror 310 which is not present in the switching voltage converter 100 of FIG. 1, a current limit clamp circuit 320 which is different than the current limit clamp circuit 120 of FIG. 1, and a PFET MP7 instead of NFET MN5 in FIG. 1. Further, and as described below, the control loop for clamping the amplifier's output voltage EA_OUT includes the slope compensation current ISLOPE rather than ISLOPE being generated outside that loop as described above regarding FIG. 1.

In this example, current mirror 310 includes transistors MN31, MN32, and MN33, all NFETs but can be implemented as other types of transistors. The gates of transistors MN31-MN33 are coupled together, and the sources of transistors MN31-MN33 are coupled together. Current mirror 310 includes a current mirror input 311 and current mirror outputs 312 and 313. The current input 161 of the slope generation circuit 160 is coupled to the current mirror input 311 of current mirror 310. The current mirror output 312 is coupled to the gate of transistor MP7 and to the drain of transistor MP34 (described below). Transistor MP7 is coupled between the amplifier's output 103 and the reference terminal 136.

The current limit clamp circuit 320 is largely the same as the current limit clamp circuit 120 of FIG. 1 but with the addition of transistor MP35 (e.g., a PFET) coupled to transistor MP1 to form a current mirror in which the current through transistor MP35 is mirrored through transistor MP1. By contrast, in FIG. 1 transistor MP1 is mirrored with transistor MP4.

As described above, the VtoI converter circuit 110 converts the amplifier's output voltage EA_OUT to a current I4. Current I4 from transistor MP4 of the VtoI converter circuit 110 divides between the slope compensation current ISLOPE and current I31 through transistor MN31. Accordingly, current I31 is a function of the difference between currents I4 and ISLOPE. All else being equal, as ISLOPE increases, current I31 decreases, and as current ISLOPE decreases, current I31 increases.

The switching voltage converter 300 also includes transistor MP34 (e.g., a PFET) coupled between the internal supply voltage rail VCC and as described above, the drain of transistor MN32 (which is a current mirror output 312). Transistor MP34 is biased with a fixed voltage IBIAS1 and thus produces a fixed drain current I35. For the switching voltage converter 300, transistor MP7 used to limit the amplifier's output voltage EA_OUT is controlled by the voltage on the drains of transistors MP34 and MN32. In this example and as further described below, the control loop to limit the amplifier's output voltage EA_OUT includes the slope compensation current ISLOPE. By contrast, for the switching voltage converter 100 of FIG. 1, the slope compensation current ISLOPE is outside the control loop for the amplifier's output voltage EA_OUT.

As EA_OUT increases, current I4 also increases. The slope compensation current ISLOPE is subtracted from current I4 resulting in current I31 through transistor MN31. When the magnitude of current I31 (and thus mirrored current I32) is smaller than the magnitude of fixed current I35 through transistor MP34, current flows into the gate of transistor MP7 and charges the gate-to-source capacitance of transistor MP7 thereby maintaining transistor MP7 in an OFF state.

When the magnitude of current I31 (and thus mirrored current I32) exceeds the magnitude of current I35 through transistor MP34, the gate-to source capacitance of transistor MP7 discharges as current flows from the gate of transistor MP7 and through transistor MN32 to the reference terminal 136 thereby turning ON transistor MP7. The magnitude of current I32 resulting in transistor MP7 turning ON is a function of the fixed current I35 through transistor MP34—transistor MP7 turns ON when current I32 exceeds the fixed current I35. However, the magnitude of the amplifier's output voltage EA_OUT that results (via VtoI converter circuit 110 and current mirror 310) in current I32 exceeding current I35 is a function of both the magnitude of voltage EA_OUT and the magnitude of the slope compensation current ISLOPE. Accordingly, transistor MP7 will turn ON responsive to different magnitudes of the amplifier's output voltage EA_OUT based on varying levels of the slope compensation current ISLOPE.

For example, consider two levels of the slope compensation current—a lower level and a higher level. For the slope compensation current ISLOPE is at the lower level, transistor MP7 will turn ON responsive to a smaller level of voltage EA_OUT. For the slope compensation current ISLOPE is at the higher level, transistor MP7 will turn ON responsive to a larger level of voltage EA_OUT because EA_OUT will need to be larger to result in a sufficiently high level of current I32 to cause transistor MP7 to turn ON.

The voltage at which EA_OUT is clamped by the control loop formed by transistors MN31, MN32, and MP7 will vary based on the magnitude of the slope compensation current ISLOPE, which itself may vary based on, for example, the magnitude of the duty cycle. However, the magnitude of current I32 which causes transistor MP7 to turn ON is a function of the fixed current I35 and scales with the magnitude of the slope compensation current ISLOPE. Current I32 is mirrored through transistor MN33 as current I33. The slope compensation current ISLOPE becoming large causes the control loop for the clamp of the amplifier's output voltage EA_OUT to dynamically to adjust to different voltage levels (based, in part, on ISLOPE) and does not cause a reduction in the currents through the current limit clamp circuit 320. Accordingly, the inductor current IL is able to reach and be clamped at the target upper limit 210 described above, whereas, as described above for the switching voltage converter 100 of FIG. 1, higher levels of the slope compensation current may prevent the inductor current from reaching the upper limit 210.

Current I33 is mirrored through transistor MP1 as current I6. The portion of the current limit clamp circuit 320 including transistors MP1-MP3 and MN1-MN3 operates the same as described above regarding the current limit clamp circuit 120 of FIG. 1.

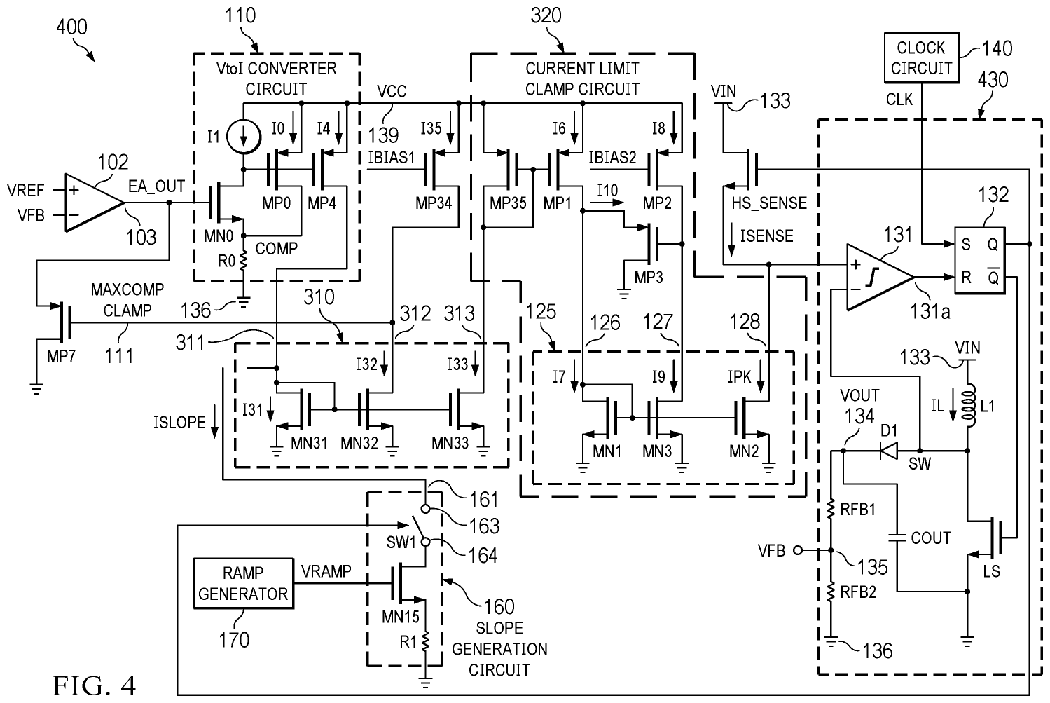

FIG. 4 is a schematic diagram of a switching voltage converter 400 which is largely the same as the switching voltage converter 300 of FIG. 3—and thus a description of the common circuitry is not repeated here. A difference between the switching voltage converters 300 and 400 is the power stage circuit. The switching voltage converter 400 includes a power stage circuit 430 that is different than the power stage circuit 130 of FIG. 3. The power stage circuit 430 of FIG. 4 is for a boost converter. The example power stage circuit 430 includes an inductor L1, a diode D1, an output capacitor COUT, and an LS transistor. The inductor L1 is coupled between the voltage input terminal 133 and the drain of the LS transistor and the anode of diode D1. The output capacitor COUT is coupled between the cathode of diode D1 and the source of the LS transistor.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Multiple current mirrors are described herein. The current mirror ratios for the various current mirrors are application-specific and can vary from current mirror to current mirror. In general, a given current mirror may have a current mirror ratio of M:1 or M:N:1, where M and/or N is 1 or another value.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A voltage converter, comprising:
an amplifier having an amplifier output;
a voltage-to-current (VtoI) converter circuit having a VtoI input and a VtoI output, the VtoI input coupled to the amplifier output;
a current mirror having a current mirror input and a current mirror output, the current mirror input coupled to the VtoI output;
a slope generation circuit having an input coupled to the current mirror input; and
a transistor coupled between the amplifier output and a reference terminal, the transistor having a control input coupled to the current mirror output.

2. The voltage converter of claim 1, wherein the transistor is a first transistor, the current mirror output is a first current mirror output, the current mirror has a second current mirror output, and the voltage converter further comprises:
a current limit clamp circuit having an input coupled to the second current mirror output and having a current limit clamp circuit output;
a second transistor coupled between an input voltage terminal and the current limit clamp circuit output; and
a comparator having an input coupled to the second transistor and to the current limit clamp circuit output.

3. The voltage converter of claim 2, wherein the transistor is a first transistor, and the voltage converter comprises a second transistor coupled between a input voltage terminal and the first current mirror output.

4. The voltage converter of claim 1, wherein the voltage converter comprises a buck converter, a boost converter, or a buck-boost converter.

5. The voltage converter of claim 1, wherein the current mirror is a first current mirror, the current mirror output is a first current mirror output, and the VtoI converter circuit comprises a second current mirror having a second current mirror output coupled to the VtoI output.

6. A voltage converter, comprising:
an amplifier having an amplifier output;
a voltage-to-current (VtoI) converter circuit coupled to the amplifier output, the VtoI converter circuit having a VtoI output, the VtoI converter circuit configured to convert a voltage at the amplifier output to a first current;
a slope generation circuit having an input coupled to the VtoI output, the slope generation circuit configured to generate a slope compensation current;
a current mirror having a current mirror input and a current mirror output, the current mirror input coupled to the VtoI output, the current mirror configured to mirror a difference between the first current and the slope compensation current as a second current;
a first transistor coupled between an input voltage terminal and the current mirror output; and
a second transistor coupled between the amplifier output and a reference terminal, the second transistor having a control input coupled to the current mirror output.

7. The voltage converter of claim 6, wherein the current mirror output is a first current mirror output, the current mirror has a second current mirror output, and the voltage converter further comprises:
a current limit clamp circuit having an input coupled to the second current mirror output and having a current limit clamp circuit output;
a third transistor coupled between the input voltage terminal and the current limit clamp circuit output; and
a comparator having an input coupled to the current limit clamp circuit output.

8. The voltage converter of claim 6, wherein the voltage converter comprises a buck converter, a boost converter, or a buck-boost converter.

9. The voltage converter of claim 6, wherein the current mirror is a first current mirror, the current mirror output is a first current mirror output, and the VtoI converter circuit comprises a second current mirror having a second current mirror output coupled to the VtoI output.

10. A circuit, comprising:
an amplifier having an amplifier output; and
a control loop coupled to the amplifier output, the control loop including:
a first transistor having a source coupled to the amplifier output;
a current mirror circuit having an input and an output, wherein:
the input is coupled to a first current associated with the amplifier;
the input is coupled to a second current associated with a slope generation circuit; and
the output is coupled with a gate of the first transistor; and
a second transistor having a drain coupled with the amplifier output.

11. The circuit of claim 10, wherein:
the first current is output from a voltage-to-current (VtoI) converter circuit; and
the VtoI converter circuit is coupled to the amplifier output.

12. The circuit of claim 10, wherein:
the output of the current mirror circuit is a first output; and
the current mirror circuit includes a second output coupled to a current limit clamp circuit.

13. The circuit of claim 12, wherein:
the current mirror circuit includes a third transistor, a fourth transistor, and a fifth transistor.

14. The circuit of claim 13, wherein:
the third transistor includes a drain coupled to the input of the current mirror circuit;
the fourth transistor includes a drain coupled to the first output of the current mirror circuit; and
the fifth transistor includes a drain coupled to the second output of the current mirror circuit.

15. The circuit of claim 13, wherein:
the third transistor includes a gate and a drain; and
the gate of the third transistor is coupled to the drain of the third transistor.

16. The circuit of claim 13, wherein:
a gate of the third transistor is coupled with a gate of the fourth transistor and a gate of the fifth transistor.

17. The circuit of claim 10, wherein:
the slope generation circuit is coupled to a ramp generator and a power stage circuit.

18. The circuit of claim 17, wherein:
the power stage circuit includes a comparator coupled to a flip-flop having an output.

19. The circuit of claim 18, wherein:
the output of the power stage circuit is coupled to the slope generation circuit.

20. The circuit of claim 17, wherein:
the power stage circuit includes a feedback output coupled to a first input of the amplifier; and
a voltage reference is coupled to a second input of the amplifier.
